(19) United States
(12) Patent Application Publication
(10) Pub. No.: US 2011/0003254 A1
(43) Pub. Date: Jan. 6, 2011

(54) LAYOUT DECOMPOSITION METHOD APPLICABLE TO A DUAL-PATTERN LITHOGRAPHY

(75) Inventors: Yao-Wen Chang, Taipei (TW); Huang-Yu Chen, Taipei (TW)

Correspondence Address: EDWARDS ANGELL PALMER & DODGE LLP, P.O. BOX 55874, BOSTON, MA, 02205, US

(73) Assignee: NATIONAL TAIWAN UNIVERSITY, Taipei (TW)

(21) Appl. No.: 12/829,437

(22) Filed: Jul. 2, 2010

(30) Foreign Application Priority Data
Jul. 6, 2009 (TW) 98122721

(51) Int. Cl. G03F 7/20

(52) U.S. Cl. 430/322

(57) ABSTRACT

A layout decomposition method, applicable to a double pattern lithography, includes the steps of: putting at least a stitch on each of a plurality of sub-patterns of an initial layout pattern at preset intervals to thereby divide the each of the plurality of sub-patterns into a plurality of unit blocks each selectively labeled as a first region or a second region such that the first region and the second region in same said sub-pattern alternate, wherein any two neighboring ones of said unit blocks attributed to any two neighboring ones of said sub-patterns, respectively, are labeled as the first region and the second region, respectively; reducing the stitches of any two neighboring ones of said unit blocks attributed to any two neighboring ones of said sub-patterns, respectively, so as to generate a first layout pattern having a minimum number of stitches; and reducing the stitches of any two contiguous ones of said unit blocks of each of said sub-patterns in the first layout pattern, so as to generate a second layout pattern having a minimum number of stitches.

### BACKGROUND OF THE INVENTION

1. Field of the Invention

This invention relates to layout decomposition methods applicable to double pattern lithography, and more particularly, to a layout decomposition method including a pre-process whereby a layout pattern on a single mask is decomposed and mapped to two masks.

2. Description of Related Art

With the rapid development of the integrated circuit fabrication processes, cells in a modern integrated circuit are fabricated in a more compact manner and have smaller pitches, as compared with cells in a conventional integrated circuit. For example, pitch requirements for integrated circuit fabrication processes have evolved from deep submicron meter level (e.g., 0.13 micron fabrication process) to nanometer level (e.g., 45 nanometer fabrication process). Accordingly, lithography has to be precisely performed in order for layout patterns to be exactly exposed via a mask before being mapped to a semiconductor wafer. Lithography nowadays is confronted with unsolved problems. For instance, small cell pitches worsen the layout pattern distortion due to light diffraction and affect the reliability of the integrated circuit fabrication process. According to the diffraction limit theory, an exposure light source with a short wavelength or a lens with a great numerical aperture (NA) may form an integrated circuit with small cell pitches. However, the exposure light source with a short wavelength or the lens with a great NA has to work with a variety of sophisticated equipment, such as an exposure machine and photo resist, and therefore costs a lot of money.

According to the International Technology Roadmap for Semiconductors, (ITRS), it is common in the art to apply double pattern technology (DPT) to extend an immerse lithography technology to 16 nanometers. The DPT enables integrated circuit-based layout patterns on a single mask to be decomposed and mapped to two masks, and obtains layout patterns of finer pitches by double exposure technology.

Double pattern lithography technology whereby layout patterns on a single mask are decomposed and mapped to two masks (using a layout decomposition technique) reduces layout pattern pitches at the cost of unsolved problems, including pattern conflicts and stitches. Pattern conflicts arise when a distance between two masks obtained by the layout decomposition technique is less than or equal to a minimum cell pitch defined by a pattern design rule (i.e., a splitting distance) because of the shape of the layout pattern or corresponding location relations between sub-patterns. In practice, pattern conflicts are avoided by adding stitches to the sub-patterns where the two masks conflict. Stitches refer to the dividing points between different masks on the same sub-pattern. Stitches greatly undermine the reliability of the integrated circuit fabrication process, and reduce the printability of the layout patterns.

In conclusion, for the integrated circuit fabrication process the use of the double pattern lithography technology to extend the scalability of an integrated circuit and improve the cell efficiency is one of the most cost-effective resolutions in the art. However, pattern conflicts caused by the layout decomposition technique whereby layout patterns on a single mask are decomposed and mapped to two masks are avoided, in practice, by adding stitches to the sub-patterns where the masks conflict. Persons skilled in the art are concerned about the following: the stitches, though solving the pattern conflict problems, flaw the layout patterns during the fabrication process, and reduce the reliability of the integrated circuit layout or circuit cells.

In view of the increase in the number of stitches due to the application of the layout pattern decomposition technique to the double pattern lithography technology, it is imperative to implement layout decomposition in the double pattern lithography technology in a way effective in avoiding pattern conflicts and minimizing the number of stitches.

### SUMMARY OF THE INVENTION

In view of the above-mentioned problems with the prior art, the present invention provides a layout decomposition method applicable to the double pattern lithography technology so as for layout patterns on a single mask to be decomposed and mapped to two masks and advantageously allows resultant integrated circuit-based layout patterns to have relatively fine layout pattern pitches to thereby greatly reduce the numbers of pattern conflicts and stitches otherwise arising from conventional layout decomposition and improve the reliability of the integrated circuit fabrication process.

The layout decomposition method includes the steps of generating each of a plurality of sub-patterns of an initial layout pattern comprising at least a unit block, and expressing each of the unit blocks by a first region or a second region, in which adjacent said unit blocks aligned horizontally and vertically in the initial layout pattern, respectively, differ from each other in terms of the regions so as for pattern conflicts to be removed by alternate regions; reducing the stitches of any two neighboring ones of said unit blocks attributed to any two neighboring ones of said sub-patterns, respectively, so as to generate a first layout pattern having a minimum number of stitches; and reducing the stitches of any two contiguous ones of said unit blocks of each of said sub-patterns in the first layout pattern, so as to generate a second layout pattern having a minimum number of stitches.

Unlike the prior art, a layout decomposition method applicable to double pattern lithography technology according to the present invention uses the alternate regions to remove pattern conflicts to ensure that resultant layout patterns are free from pattern conflicts, and minimizes the number of stitches in the sub-patterns of the alternate regions, to generate a final layout pattern. Therefore, the number of stitches of each sub-pattern is reduced on condition that no new pattern conflict arises. Accordingly, the layout decomposition method applicable to the double pattern lithography technology according to the present invention may further improve the printability of the layout patterns and the reliability of the produced integrated circuit.

### BRIEF DESCRIPTION OF DRAWINGS

FIG. 1 is a schematic diagram illustrating that a layout decomposition method applicable to double pattern lithography technology according to the present invention uses alternate regions to remove pattern conflicts;

FIG. 2 is a partial schematic diagram illustrating that a layout decomposition method applicable to double pattern lithography technology in another embodiment according to the present invention uses alternate color regions to remove pattern conflicts;

FIGS. 3A and 3B are schematic diagrams of implementation of minimization of the number of stitches in sub-patterns of a layout pattern by a layout decomposition method applicable to double pattern lithography technology after removal of pattern conflicts from the layout pattern by alternate regions according to the present invention;

FIG. 4 is a schematic diagram that further illustrates the implementation of minimization of the number of the stitches in the sub-patterns shown in FIGS. 3A and 3B;

FIG. 5 is a schematic diagram further illustrating the implementation of minimization of the number of stitches shown in FIGS. 3A and 3B with considerations given to weights of node chains of layout patterns and the link relations between the node chains;

FIGS. 6A and 6B are schematic diagrams of implementation of minimization of the number of stitches in sub-patterns by a layout decomposition method applicable to a double pattern lithography technology according to the present invention; and

FIG. 7 is a flow chart of a layout decomposition method applicable to a double pattern lithography technology in an embodiment according to the present invention.

### DETAILED DESCRIPTION OF PREFERRED EMBODIMENTS

The following illustrative embodiments are provided to illustrate the disclosure of the present invention; these and other advantages and effects can be apparently understood by those in the art after reading the disclosure of this specification. The present invention can also be performed or applied by other different embodiments. Details described in the specification can be modified and changed according to different points and applications. Numerous modifications and variations can be devised without departing from the spirit of the present invention.

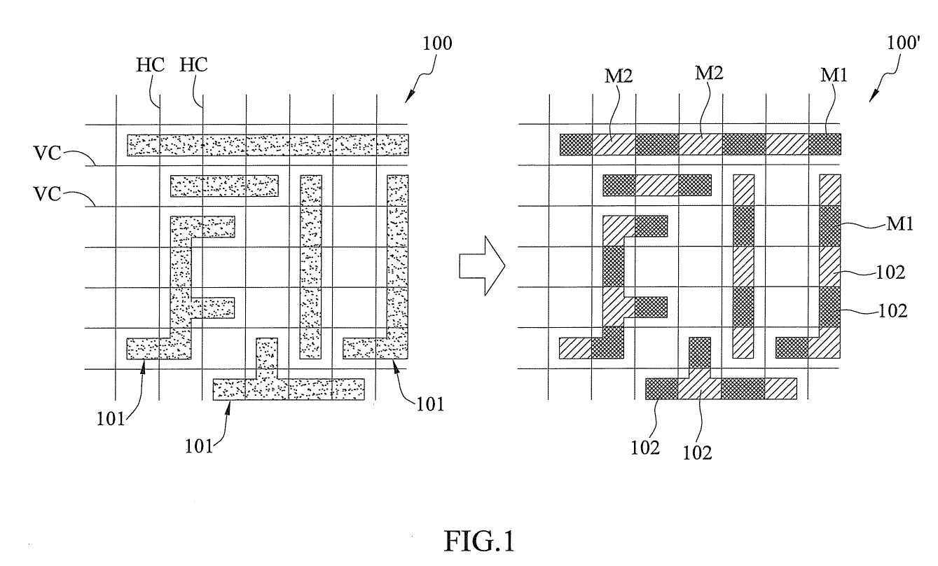

Referring to FIG. 1, there is shown a partial schematic diagram of a layout decomposition method applicable to a double pattern lithography technology according to the present invention, for removing pattern conflicts by using alternate regions. As shown in the drawing, an initial layout pattern is disposed in a two-dimensional coordinate system having horizontal coordinates HC and vertical coordinates VC. The unit length of the two-dimensional coordinate system may be changed according to the demands of an integrated circuit fabrication process, such that all sub-patterns 101 in the initial layout pattern 100 are spaced from one another at least in a minimum cell pitch that complies with a pattern design rule of the integrated circuit fabrication process. Moreover, during the process that the unit length of the coordinate system is shortened or lengthened, all of the sub-patterns 101 are shortened or lengthened in accordance with the shortening or lengthening of the unit length, but have their relative location relations be unchanged. In other words, the relative location relations of the sub-patterns 101 will not change with the shortening or lengthening of the unit length of the coordinate system.

A layout pattern 100′ shown in FIG. 1 is disposed in a plurality of grid boxes defined by the horizontal coordinates HC and the vertical coordinates VC. Note that both the length and the width of each of the grid boxes have to be greater than the minimum cell pitch defined by the pattern design rule. A partial or complete sub-pattern 101 covered by any one of the grid boxes defines a unit block 102, such that the sub-patterns 101 comprise at least one of the unit blocks 102. To prevent pattern conflicts from occurring to the layout pattern 100′, the unit blocks 102 covered by adjacent said grid boxes (including adjacent said grid boxes aligned horizontally and vertically, respectively) are assigned to a first color region M1 and a second color region M2 (to distinguish the first region and the second region by color herein or selectively distinguish the first region and the second region by chromatic, numeral, graphic, or textural), respectively, such that the unit blocks 102 covered by all adjacent said grid boxes are attributed to different color regions corresponding to respective masks.

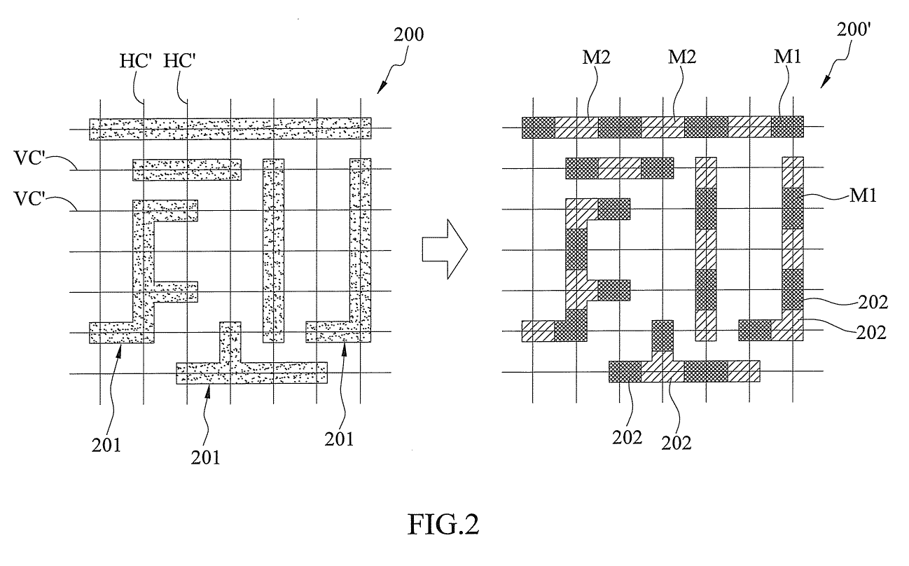

Referring to FIG. 2, there is shown a partial schematic diagram of a layout decomposition method applicable to a double pattern lithography technology of another embodiment according to the present invention, for removing pattern conflicts by using alternate color regions. FIG. 2 differs from FIG. 1 in that an initial layout pattern 200 and unit blocks 202 of a layout pattern 200′ are not limited to be covered in the grid boxes of the two-dimensional coordinate system. The unit blocks 202 may be positioned at points each uniquely identified by a corresponding one of horizontal coordinates HC′ and a corresponding one of vertical coordinates VC′. Compared with the layout patterns 100 and 100′ shown in FIG. 1, the layout patterns 200 and 200′ shown in FIG. 2 shift as far as a half of one grid box in the horizontal direction and in the vertical direction, with the relative location relations of the sub-patterns 201 unchanged.

Therefore, the layout decomposition method applicable to the double pattern lithography technology according to the present invention involves using alternate color regions to remove patterns conflicts so as to ensure that the sub-patterns will be free from pattern conflict after the masks are assigned.

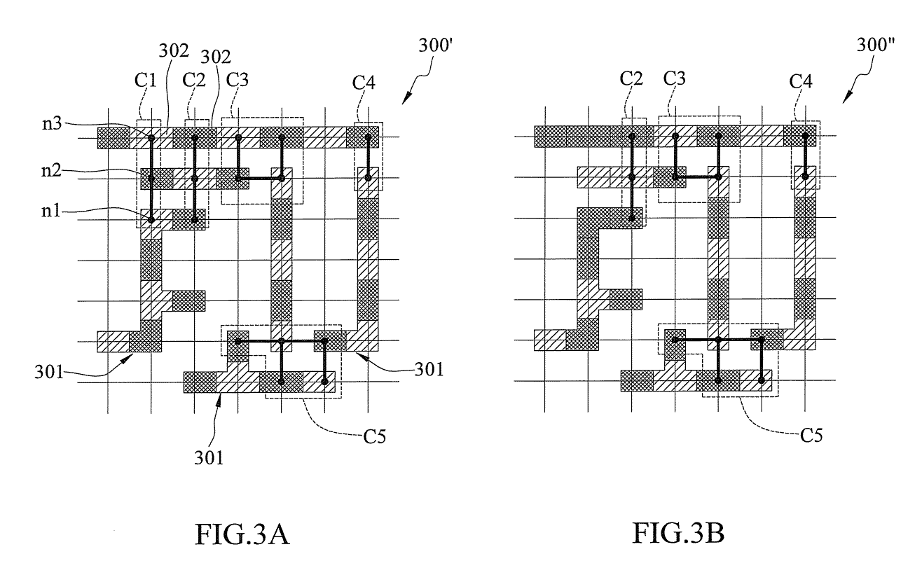

Referring to FIGS. 3A and 3B, there are shown schematic diagrams of implementation of minimization of the number of stitches in sub-patterns of a layout pattern 300′ by a layout decomposition method applicable to double pattern lithography technology after removal of pattern conflicts from the layout pattern 300′ by alternate color regions according to the present invention. When the unit block 302 on the sub-pattern 301 is adjacent to the unit block 302 on other sub-pattern 301, the unit block 302 is defined to be a node. The two unit blocks are adjacent because two said unit blocks 302 are covered in two adjacent grid boxes in the horizontal direction and in the vertical direction, respectively. As shown in FIG. 3A, the reference numerals n1, n2 and n3 of the unit blocks 302 on the sub-pattern 301 may define a node. Accordingly, a solid circle shown in FIG. 3A indicates a node.

Then, links between a plurality of adjacent nodes located on different sub-patterns are created, and each of the links is defined as a node chain. For example, nodes n1 and n2 are located on different sub-patterns and are covered in two adjacent grid boxes, and a link n1-n2 may be created. Similarly, another link n2-n3 may be created between nodes n2 and n3. It can be thus known that the nodes n1, n2 and n3 may form a node chain C1. As shown in FIG. 3A, five node chains C1, C2, C3, C4 and C5 are created in the layout pattern. The weights of the node chains provide very important and critical references for the step that further reduces the number of stitches. The weights of the node chains mean the number of stitches that may be reduced when color regions of all the nodes of a node chain are changed on condition that no new pattern conflict arises. For example, as shown in FIG. 3A, the color regions of all the nodes n1, n2 and n3 of the node chain C1 are changed, and the node n1 initially attributed to the second mask becomes attributable to the first mask, while the node n2 initially attributed to the first mask becomes attributable to the second mask, and so on. Then, as shown in FIG. 3B, once the nodes n1, n2 and n3 of the node chain C1 have their color regions changed, the number of the stitches of the layout pattern 300″ in its entirety is reduced by five, which is the weight of the node chain C1.

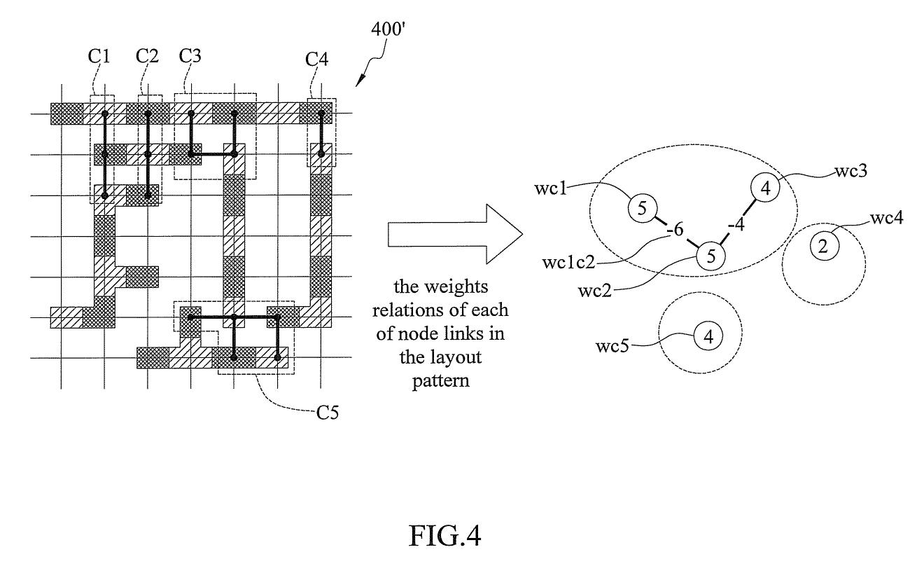

Referring to FIG. 4, there is shown a schematic diagram that further illustrates the implementation of minimization of the number of the stitches in the sub-patterns shown in FIGS. 3A and 3B. The weights of node chains in the layout pattern 400′ are calculated, respectively. The number of stitches that may be reduced is calculated when the color regions of all the nodes in a single node chain are changed on condition that no new pattern conflict arises.

Referring to FIG. 4 again, if the nodes n1, n2 and n3 of the node chain C1 have their color regions changed, the number of stitches of the layout pattern 400′ in its entirety is reduced by five (i.e., c1 weight wc1=5). Similarly, if all the nodes of the node chain C2 have their color regions changed, the stitches of the layout pattern in its entirety is reduced by five (i.e., c2 weight wc2=5) too. Therefore, C3 weight wc3=4, C4 weight wc4=2, and C5 weight wc5=4. However, note that since the node chains C1, C2, C3, C4 and C5 may be linked to one another, the simultaneous changing of the color regions of all the nodes of two adjacent node chains may lead to unexpected reduction of the number of stitches. For example, the simultaneous changing of color regions of all the nodes of the node chain C1 and the node chain C2 reduces the number of stitches by four, that is wc1+wc2+wc1c2=4 (which means that a reciprocal weight wc1c2 resulting from the simultaneous changing of the node chain C1 and the node chain C2 is equal to −6).

Therefore, in calculating a node chain which has the greatest reduction of the number of stitches and in which all the nodes of the node chains get the greatest reduction of the number of stitches if their color regions are changed, the weights of the node chains and link relations between the node chains have to be considered on condition that no new pattern conflict arises. For example, as shown in the drawings the node chains C1, C2, C3, C4 and C5 have weights equal to 5, 5, 4, 2 and 4, respectively, and the reciprocal weight between C1 and C2 is −6. Consequently, the number of stitches reduced due to the simultaneous changing of color regions of C1 and C2 is 5+5−6=4, which is a remarkable effect for the stitch reduction.

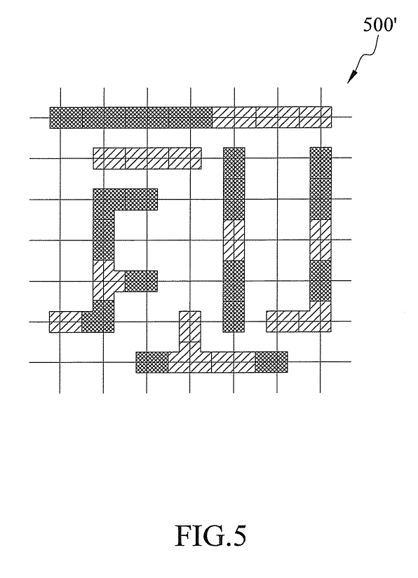

In order to avoid the generation of pattern conflicts due to the changing of color regions between sub-patterns of a layout pattern, the layout decomposition method applicable to the double pattern lithography technology according to the present invention, when performing a stitch step on sub-patterns, considers both the weights of the node chains C1, C2, C3, C4 and C5 of the layout pattern 400′ and the link relations between the node chains C1, C2, C3, C4 and C5, and finds a node chain that has the greatest reduction of the number of stitches. According to the embodiment, the node chain that has the greatest reduction of the number of stitches is {C1,C3,C4,C5}. Accordingly, through the simultaneous changing of color regions of the node chains {C1,C3,C4,C5}, as shown in FIG. 5, the number of stitches of the layout pattern 500′ may be reduced from 27 to 12. Therefore, the layout decomposition method applicable to the double pattern lithography technology according to the present invention uses the alternate color regions to remove pattern conflicts and thereby effectively reduces the number of stitches, by minimizing the number of stitches in sub-patterns on condition that no new pattern conflict arises in the course of minimization of stitches.

Moreover, note that for different integrated circuit fabrication processes or the demands of cell characteristics, the layout decomposition method applicable to the double pattern lithography technology according to the present invention assigns all unit blocks in a certain sub-pattern to the same color region so as to maintain the performance of some certain cells or circuit blocks decomposed and mapped to two masks. For example, considering that the performance and electric characteristics of transistors or inductors in an integrated circuit fabrication process depend on the shape and height of the cells, if the cells on a single mask are decomposed and mapped to two masks, the performance and characteristics of the cells are likely to be greatly impacted because of the slight mismatch generated at the intersections of the patterns of the two masks. Thus, the layout decomposition method applicable to the double pattern lithography technology according to the present invention assigns certain cells or circuit blocks to a mask according to fabrication process characteristics and cell demands.

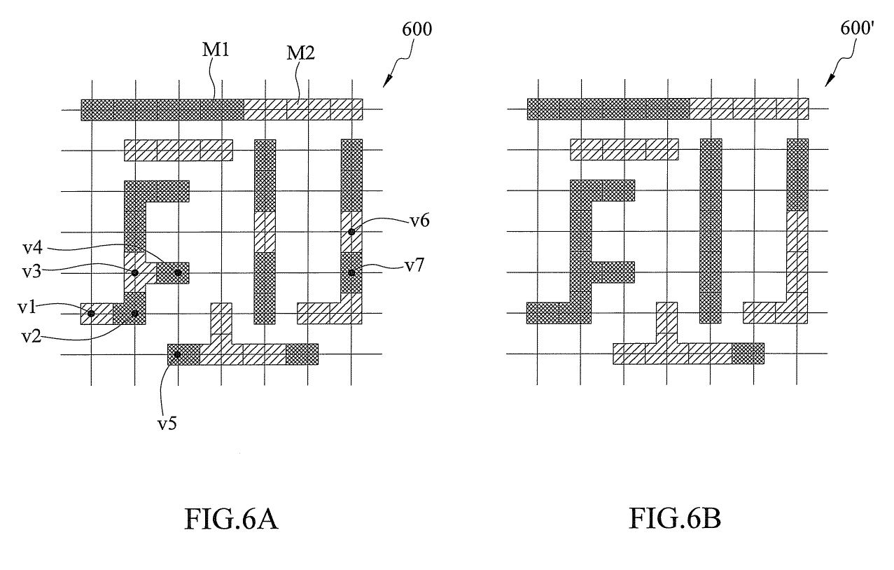

Referring to FIGS. 6A and 6B, there are shown schematic diagrams of implementation of minimization of the number of stitches in sub-patterns by the layout decomposition method applicable to the double pattern lithography technology according to the present invention. The number of stitches in the sub-patterns of the layout pattern 500′, the number of pattern sub-patterns of which has already be minimized, is further minimized. If a unit block and another unit block adjacent thereto are located at the same sub-pattern but attributed to different color regions, the unit blocks are together defined as an inner node. For example, as shown in FIG. 6A, since unit blocks v1 and v2 are located at the same sub-pattern and are covered in two adjacent grid boxes aligned horizontally and vertically, respectively, the unit blocks v1 and v2 are both defined as an inner node. Similarly, v3 to v7 each is also defined as an inner node.

Then the weight of each inner node is calculated individually, that is, by calculating the number of stitches reduced due to the changing of the color region of an inner node on condition that no new pattern conflict arises. For example, as shown in FIG. 6A, the color region of the inner node v1 in the layout pattern 600 is changed. In other words, the inner node v1 initially attributed to the second color region M2 becomes attributable to the first color region M1, while the inner node v2 initially attributed to the first tine layer M1 becomes attributable to the second color region M2, and so on. Once the color region of the inner node v2 is changed, the number of the stitches of the layout pattern in its entirety is reduced by two, i.e., the weight of the inner node v2.

As shown in FIG. 6B, considerations are given to the weights of the inner nodes and the link relations between the inner nodes on condition that no new pattern conflict arises, and the set of inner nodes that has the greatest reduction of the number of stitches is calculated (that is the greatest reduction of the number of stitches that all inner nodes in the set of inner nodes that have color regions changed can get), to change the color regions of the set of inner nodes. For example, the weights of the inner nodes v1, v2, v3, v4, v5, v6 and v7 are 1, 2, 3, 1, 1, 2 and 2, respectively. The simultaneous changing of color regions of v1 and v2 reduces the number of stitches by 1+2−2=1, indicating that the stitch reduction thus achieved lessens greatly and undesirably.

Therefore, the weights of the inner nodes v1, v2, v3, v4, v5, v6 and v7 and the link relations between the inner nodes v1, v2, v3, v4, v5, v6 and v7 are taken into account, and the set of inner nodes that has the greatest reduction of the number of stitches is calculated to be {v1,v3,v5,v7}. Thus, the simultaneous changing of color regions of the set of inner nodes {v1,v3,v5,v7}, as the layout pattern 600′ shown in FIG. 6B, reduces the number of stitches of the layout pattern 600′ from 12 to 3. Therefore, implementation of minimization of the number of stitches in the sub-patterns on condition that no new pattern conflict arises effectively reduces the number of stitches.

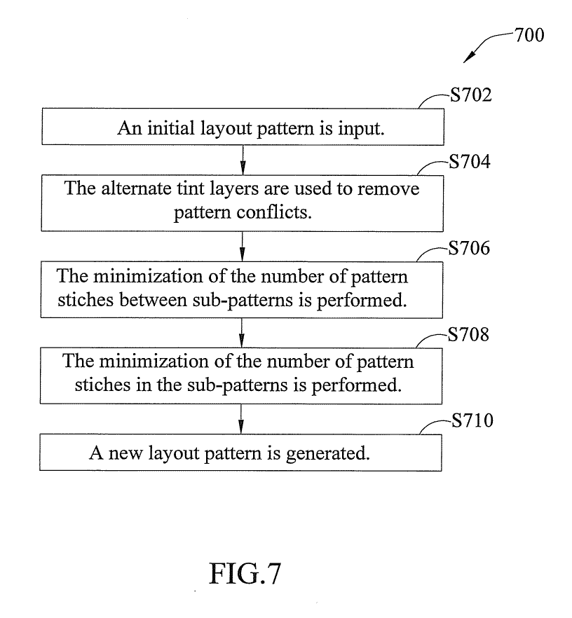

Referring to FIG. 7, there is shown a flow chart of a layout decomposition method 700 applicable to the double pattern lithography technology according to the present invention. The method 700 starts from step S702. In step S702, an initial layout pattern is input, before going to step S704. In step S704, the alternate color regions are used to remove pattern conflicts. Each sub-pattern. In the layout pattern is cut to form a set comprising at least a unit block, and the unit blocks are labeled as the first color region and the second color region, respectively, to allow all adjacent said unit blocks aligned horizontally and vertically, respectively, to be attributed to different color regions. Proceed to step S706. Step S706 involves performing minimization of the number of stitches in sub-patterns, calculating the weight of each node chain, giving considerations to the weights of the node chains and the link relations between the node chains on condition that no new pattern conflict arises, calculating a node chain fit for the greatest reduction of the number of stitches, and changing the color regions of all the nodes in the node chain. Proceed to step S708. Step S708 involves performing minimization of the number of stitches in the sub-patterns, calculating the weight of each inner node, giving considerations to the weights of the node chains and the link relations between the node chains on condition that no new pattern conflict arises, calculating the set of inner nodes fit for the greatest reduction of the number of stitches, and changing the color regions of all inner nodes in the set of inner nodes. Proceed to step S710. In step S710, the layout-decomposed layout pattern is generated.

Unlike the prior art, the layout decomposition method applicable to the double pattern lithography technology according to the present invention greatly reduces the number of stitches, and greatly reduces the chance that flaws or malfunctions occur to the integrated circuit fabrication process. Therefore, the layout decomposition method applicable to the double pattern lithography technology according to the present invention further improves the printability of the integrated circuit layout patterns and the reliability of the produced integrated circuit.

The foregoing descriptions of the detailed embodiments are illustrated to disclose the features and functions of the present invention but are not restrictive of the scope of the present invention. It should be comprehensible to those in the art that all modifications and changes made to the embodiments according to the spirit and principle embodied in the disclosure of the present invention should fall within the scope of the appended claims.

What is claimed is:

1. A layout decomposition method, applicable to a double pattern lithography, comprising the steps of:
(1) putting at least a stitch on each of a plurality of sub-patterns of an initial layout pattern at preset intervals to thereby divide the each of the plurality of sub-patterns into a plurality of unit blocks each selectively labeled as a first region or a second region such that the first region and the second region in same said sub-pattern alternate, wherein any two neighboring ones of said unit blocks attributed to any two neighboring ones of said sub-patterns, respectively, are labeled as the first region and the second region, respectively;
(2) reducing the stitches of any two neighboring ones of said unit blocks attributed to any two neighboring ones of said sub-patterns, respectively, so as to generate a first layout pattern having a minimum number of stitches; and
(3) reducing the stitches of any two contiguous ones of said unit blocks of each of said sub-patterns in the first layout pattern, so as to generate a second layout pattern having a minimum number of stitches.

2. The layout decomposition method of claim 1, further comprising the step of:
presetting a two-dimensional coordinate system having horizontal coordinates and vertical coordinates so as for the initial layout pattern to be disposed in the two-dimensional coordinate system and the sub-patterns of the initial layout pattern to have predetermined relative locations in the two-dimensional coordinate system.

3. The layout decomposition method of claim 2, wherein the two-dimensional coordinate system comprises a plurality of grid boxes for receiving therein the unit blocks of the initial layout pattern, respectively.

4. The layout decomposition method of claim 3, wherein the grid boxes of the two-dimensional coordinate system have a length/width greater than or equal to a minimum cell pitch defined by a pattern design rule of the initial layout pattern.

5. The layout decomposition method of claim 2, wherein the unit blocks are disposed at points each uniquely identified by a corresponding one of the horizontal coordinates and a corresponding one of the vertical coordinates of the two-dimensional coordinate system, respectively, and disposed in a plurality of grid boxes linked with the points, respectively.

6. The layout decomposition method of claim 5, wherein the grid boxes of the two-dimensional coordinate system have length/width greater than or equal to a minimum cell pitch defined by a pattern design rule of the initial layout pattern.

7. The layout decomposition method of claim 1, wherein the step (2) further comprises the steps of
(2-1) defining each one of two neighboring ones of said unit blocks attributed to any two neighboring ones of said sub-patterns as a node;
(2-2) linking a plurality of neighboring nodes located at different said sub-patterns so as to create node chains; and
(2-3) calculating a weight of each of the node chains and replacing the first regions of all the nodes in the node chains having relatively great said weight with the second regions and vice versa.

8. The layout decomposition method of claim 7, wherein neighboring said unit blocks from different said sub-patterns of the initial layout pattern are spaced-apart horizontally or vertically.

9. The layout decomposition method of claim 7, wherein the step (2-3) further comprises the step of:
obtaining the weights of the node chains and adjacency relations between the node chains, to calculate a set of the node chains having greatest reduction of the number of stitches, so as to change regions of all the nodes in all the node chains in the set of the node chains and generate the first layout pattern.

10. The layout decomposition method of claim 7, wherein the step (3) further comprises the steps of:
(3-1) defining an inner node as a said unit block having a labeled region different from another said unit block adjacent to the said unit block and attributed to the same sub-pattern; and
(3-2) calculating weights of the inner nodes and replacing the first regions of the inner nodes having relatively great said weights with the second regions and vice versa.

11. The layout decomposition method of claim 10, wherein the step (3-2) comprises the step of:
obtaining the weights of the inner nodes and adjacency relations therebetween, respectively, so as to calculate a set of the inner nodes having greatest reduction of the number of stitches, change the regions of all the inner nodes in the set of the inner node, and generate the second layout pattern.

12. The layout decomposition method of claim 1, wherein a means to distinguish the first region from the second region is chromatic, numeral, graphic, or textural.

13. The layout decomposition method of claim 12, wherein the first region and the second region are differentiated by color and thus defined as a first color region and a second color region, respectively.
